(19) United States
(12) Patent Application Publication
(10) Pub. No.: US 2009/0086548 A1
(43) Pub. Date: Apr. 2, 2009

(54) FLASH MEMORY

(75) Inventors: Yider Wu, Chu-Pei City (TW); Yung-Chung Lee, Chu-Pei City (TW)

Correspondence Address: SCHMEISER, OLSEN & WATTS, 22 CENTURY HILL DRIVE, SUITE 302, LATHAM, NY, 12110, US

(73) Assignee: EON SILICON SOLUTION, INC., Chu-Pei City (TW)

(21) Appl. No.: 11/866,018

(22) Filed: Oct. 2, 2007

(51) Int. Cl. G11C 11/34

(52) U.S. Cl. 365/185.28

(57) ABSTRACT

A flash memory applied in NAND and/or NOR flash memory has a silicon-oxide-nitride-oxide-silicon cell structure, uses channel-hot-electron injection as a write mechanism thereof to have a localized trapping characteristic, and uses hot-hole injection as an erase mechanism thereof. The flash memory uses an oxide-nitride-oxide structure to replace a floating gate, and thereby solves the problem of an entire leakage caused by a local leakage of the floating gate. The flash memory may be miniaturized without the problem of data mutual interference, and may be easily integrated into the CMOS process to largely reduce the manufacturing cost thereof. Meanwhile, the flash memory also enables faster program time and erase time.

### FIELD OF THE INVENTION

The present invention relates to a flash memory, and more particularly, to a flash memory having a silicon-oxide-nitride-oxide-silicon cell structure. The flash memory uses channel-hot-electron injection as a write mechanism thereof to have the localized trapping characteristic, and uses hot hole injection as an erase mechanism thereof to provide better program, read, and erase efficiency, faster program, read, and erase time, and larger program, read, and erase window than other types of flash memory. Moreover, the flash memory of the present invention uses an oxide-nitride-oxide structure to replace the floating gate and therefore solves the problem of an entire leakage caused by a local leakage of the floating gate.

### BACKGROUND OF THE INVENTION

A flash memory is a non volatile semiconductor memory element that performs data storage through injecting or extracting electrons into or from a floating gate. The flash memory does not need power to maintain data stored therein, and may be divided into two types, namely, NOR flash and NAND flash. The NOR flash memory is used to store codes, and the NAND flash memory is used to store data.

The nonvolatile memory plays a more and more important role in the research and development of memory element. With the popularization of portable products, such as notebook computers, digital cameras, etc., techniques in connection with the nonvolatile memory have great progress every year. The nonvolatile memory is currently widely applied in personal computers, mobile phones, digital cameras, and many other relative electronic products.

The flash memory may be divided into two major types, namely, NOR and NAND flash memory, according to its applications in program storing and data processing. The NOR flash memory is characterized in that it directly stores the codes in a chip, and randomly reads the stored codes at a high speed, enabling high system running efficiency. When the NOR flash memory is used with a portable digital electronic device having a small capacity, such as a personal digital assistant (PDA), a mobile phone, etc., it provides relatively higher cost benefit.

The NAND flash memory has a configuration different from that of the NOR flash memory. Each NAND memory cell has a size about only one half of the NOR memory cell. Nevertheless, the NAND flash memory provides higher memory capacity and is characterized in its high-speed data writing. However, the NAND flash memory does not allow random access of data for reading, and must output data sequentially. Therefore, the NAND flash memory is suitable for data storage applications, such as being used in an electronic device for mass storage of audio/visual data, a digital camera, and a hard disk device for replacement of a mechanical type hard disk. Generally speaking, the NAND flash memory may be further divided into two categories, namely, single-level cell (SLC) flash memory and multi-level cell (MLC) flash memory. The SLC flash memory has the advantages of fast operating speed and low power consumption. However, the MLC flash memory requires lower cost, compared to SLC.

FIG. 1 is a conceptual view showing a conventional nonvolatile flash memory 1, which may be, for example, an embedded nonvolatile flash memory, includes a floating gate poly1, a plurality of oxide insulating layers 11, 12, 13, a nitride layer 14, and a control gate poly2. The nonvolatile flash memory 1 traps electric charges in the floating gate poly1, which is made of a polysilicon material and is completely sealed between the oxide insulating layers 12, 13. When the electric charges trapped in the floating gate poly1 encode, the hot-electron injection or the quantum tunneling via the oxide insulating layer 13 is used to move the electric charges into or from the floating gate poly1 to thereby change the messages stored on the memory. These operations need a relative high voltage more than about ±9V. However, the oxide insulating layers 12, 13 surrounding the floating gate poly1 has a limited thickness. Therefore, to enable an embedded flash memory, for example, to process a write/erase voltage equal to or higher than ±9V, a high-voltage transistor having a relatively lower performance must be match with a transistor having high performance, low voltage of up to 1V, and input/output voltage of 2.2V or 3.3V. When the read time is shortened, the high-voltage transistor would occupy an area much larger than that occupied by the charge storing bits. This would result in an embedded flash memory occupying an even larger area. Moreover, a main problem with the flash memory with floating gate poly1 is that, any small defect in the oxide insulating layers surrounding the floating gate poly1 would result in the loss of all electric charges and accordingly, damages to the stored data.

As an element characteristic of the flash memory 1, electrons are trapped in the floating gate poly1, and whether the flash memory 1 is to memorize or not may be determined by the bias of a critical voltage applied thereto. The conventional floating gate poly1 is implemented using polysilicon. Due to an electrical conducting characteristic of the polysilicon material, any local leakage of the polysilicon-formed floating gate poly1 would cause the problem of entire leakage of the floating gate poly1. Moreover, in the case the channel-hot-electron injection is used as a write mechanism and the hot-hole injection is used as an erase mechanism of the flash memory 1, the distribution of electric charges in the floating gate poly1 would bring the flash memory 1 with the floating gate poly1 to have longer program, write, and erase time.

It is therefore tried by the inventor to develop an improved flash memory to overcome the problem of entire leakage of the floating gate caused by local leakage thereof, and to enable better data program, read, and erase efficiency, faster program, read, and erase time, and larger program, read, and erase window.

### SUMMARY OF THE INVENTION

A primary object of the present invention is to provide a flash memory applied in NAND and/or NOR flash memory. The flash memory of the present invention includes a silicon-oxide-nitride-oxide-silicon (SONOS) array, at least one source line, at least one word line (WL), and at least one bit line (BL). The SONOS array consists of a plurality of SONOS structures separately arrayed in a first and a second direction. Each of the SONOS structures includes a source, a gate, and a drain formed in the second direction, with the source and the drain exchangeable in their position. The first direction may be an X direction or a Y direction in a plane defined by the X and Y axes of a rectangular coordinate, and the second direction may be a Y direction or an X direction in a plane defined by the X and Y axes of a rectangular coordinate. The at least one source line is formed in the first direction to electrically connect the sources of all the SONOS structures to one another. The at least one word line (WL) is formed in the first direction to electrically connect the gates of all the SONOS structures to one another. The at least one bit line (BL) is formed in the second direction to electrically connect the drains of all SONOS structures to one another via at least one contact. Wherein, the bit line is isolated from the word line and the source line by an insulating layer to avoid any short circuit.

Another object of the present invention is to provide a flash memory applied in NAND and/or NOR flash memory. The flash memory of the present invention has an SONOS cell structure, and uses an oxide-nitride-oxide (ONO) film to replace a floating gate to solve the problem of an entire leakage caused by a local leakage of the floating gate.

A further object of the present invention is to provide a flash memory applied in NAND and/or NOR flash memory. The flash memory of the present invention has an SONOS cell structure, and uses an ONO film to replace a floating gate to enable miniaturization of the flash memory without the problem of data mutual interference, so that the retention of stored data is largely improved.

A still further object of the present invention is to provide a flash memory applied in NAND and/or NOR flash memory. The flash memory of the present invention has an SONOS cell structure and uses an ONO film to replace a floating gate, enabling it to be easily integrated into a CMOS process to largely reduce the manufacturing thereof, and is therefore very suitable for use as a memory element.

To achieve the above and other objects, the flash memory of the present invention has an SONOS cell structure, uses channel-hot-electron injection as a write mechanism thereof to have a localized trapping characteristic, and uses hot-hole injection as an erase mechanism thereof. And, the flash memory of the present invention uses an ONO film to replace a floating gate to solve the problem of an entire leakage caused by a local leakage of the floating gate. The flash memory of the present invention may be miniaturized without the problem of data mutual interference, so that the retention of stored data is largely improved. Moreover, the flash memory of the present invention can be easily integrated into a CMOS process to largely reduce the manufacturing thereof, and is therefore very suitable for use as a memory element.

The flash memory with the SONOS structure according to the present invention uses the channel-hot-electron injection and the hot-hole injection as a write mechanism and an erase mechanism thereof, respectively. The use of the channel-hot-electron injection as the write mechanism gives the flash memory of the present invention the characteristic of localized trapping, which is very helpful in multi-bit memory. The flash memory of the present invention may be forward read and reverse read. The flash memory with the SONOS structure has higher program/erase efficiency, faster program/erase time, and larger program/erase window than other types of flash memory with a floating gate, and is therefore more suitable for use as a memory element. Moreover, the SONOS structure is a better form for the embedded flash memory. And, since the SONOS structure is compatible with general logical process, the flash memory with the SONOS structure is more advantageous for use in consideration of the cost thereof.

In the present invention, the ONO structure is used to replace the conventional polysilicon floating gate in the prior art. With the conducting characteristic of the nitride layer that is different from the polysilicon, the problem of an entire leakage of the floating gate can be solved. In the present invention, the ONO structure may be formed by way of thermal growth and low pressure chemical vapor deposition (LPCVD). And, the ONO structure in the present invention may be of a tunneling oxide-nitride-capping oxide structure.

The tunneling oxide layer in the SONOS structure of the flash memory of the present invention may effectively control the tunneling effect. As a result, the flash memory of the present invention has enhanced data retention ability. In the present invention, the use of the ONO structure to replace a floating gate also reduces the difficulty in reading bits. It is not necessary for the present invention to use the conventional memory element, such as the floating gate in the NAND element. In the present invention, electric charges are retrieved from the insulated nitride layer between the two oxide layers. In this manner, the flash memory of the present invention is more reliable for use, and the stored current may be effectively controlled. Moreover, with the present invention, the use of photomask in producing a memory element may be reduced, the good yield of the produced memory element is increased, and the size of the memory element may be reduced.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a conceptual view showing a conventional nonvolatile flash memory;

FIG. 2 is a conceptual view showing the structure of a flash memory according to an embodiment of the present invention;

FIG. 3 is a conceptual view showing the flash memory of FIG. 2 in a program operation;

FIG. 4 is a conceptual view showing the flash memory of FIG. 2 in an erase operation;

FIG. 5 is a conceptual view showing an SONOS array structure of the flash memory of FIG. 2;

FIG. 6 is a conceptual view showing the flash memory of FIG. 2 under a reverse read bias condition;

FIG. 7 is a conceptual view showing the flash memory of FIG. 2 under another reverse read bias condition;

FIG. 8 is a conceptual view showing the flash memory of FIG. 2 under a program bias condition;

FIG. 9 is a conceptual view showing the flash memory of FIG. 2 under another program bias condition;

FIG. 10 is a conceptual view showing the flash memory of FIG. 2 under an erase bias condition; and

FIG. 11 is a conceptual view showing the flash memory of FIG. 2 under another erase bias condition.

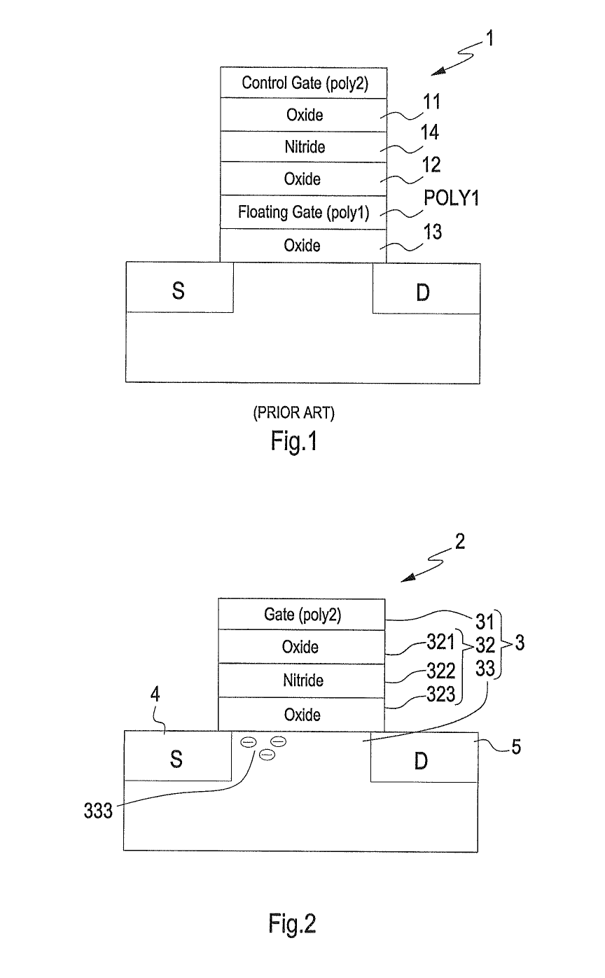

### DETAILED DESCRIPTION OF THE PREFERRED EMBODIMENTS

Please refer to FIG. 2 that is a conceptual view showing the structure of a flash memory according to an embodiment of the present invention. In the embodiment illustrated in FIG. 2, the flash memory is an n-channel silicon-oxide-nitride-oxide-silicon (SONOS) flash memory 2 consisting of a SONOS structure 3, a source 4, a drain 5, and a silicon substrate. The source 4 and the drain 5 may be exchanged in their position. That is, when the source 4 is located at the left side of the flash memory 2, the drain 5 is at the right side of the flash memory 2; and, when the source 4 is located at the right side of the flash memory 2, the drain 5 is at the left side of the flash memory 2.

The SONOS structure 3 includes a gate 31, an oxide-nitride-oxide (ONO) structure 32, and a silicon channel 33. The ONO structure 32 includes an upper oxide layer 321, a nitride layer 322, and a lower oxide layer 323. In the illustrated embodiment, the upper oxide layer 321 is of a capping oxide layer, and the lower oxide layer 323 is of a tunneling oxide layer.

To form the flash memory 2 with the SONOS structure 3, first implant boron into a silicon substrate at a dose of about 1×10¹³ cm⁻² to form a threshold voltage as a fine adjustment element of a p-well silicon substrate. Thereafter, produce a lower oxide layer 323 having a thickness of about 70 A over the p-well silicon substrate utilizing the high-temperature thermal oxidation procedure, for example. Then, a nitride layer 322 having a thickness of about 80 A is deposited on the lower oxide layer 323 by way of low pressure chemical vapor deposition (LPCVD), for example. After that, an upper oxide layer 321 having a thickness of about 95 A is deposited on the nitride layer 322 utilizing the high-temperature thermal oxidation procedure, for example. Finally, a layer of polysilicon having a thickness of about 200 nm may be deposited on the upper oxide layer 321, and an area for forming a gate 31 is defined on the polysilicon layer by way of self-align etch.

To form the source 4 and the drain 5 of the flash memory 2, an oxide layer having a thickness about 200 nm is first deposited on the silicon substrate to serve as a spacer. Then, arsenic (As) is implanted into the silicon substrate at a dose of about 1×10¹⁵ cm⁻², so as to form n+ type, n type, or n-type source 4 and drain 5.

While the flash memory 2 illustrated in FIG. 2 is an n-channel SONOS flash memory, the flash memory of the present invention may be otherwise a p-channel SONOS flash memory. Since the p-channel SONOS flash memory employs working principle and has structure corresponding to those of the n-channel SONOS flash memory 2, it is not described in details herein.

The SONOS structure 3 of the flash memory 2 uses hot-electron injection via the silicon channel 33 as a write mechanism to have the characteristic of localized trapping, and is therefore very helpful in multi-bit memory. Meanwhile, the SONOS structure 3 of the flash memory 2 uses hot-hole injection as an erase mechanism. The flash memory 2 may be forward read and reverse read. Since the flash memory of the present invention may be miniaturized in size without the problem of data mutual interference, data stored thereon may be more safely retained. Moreover, the flash memory 2 with the SONOS structure 3 can be easily integrated into the complementary metal-oxide semiconductor (CMOS) process to largely reduce the manufacturing cost thereof, and is therefore highly suitable for use as a memory element.

The flash memory 2 with the SONOS structure 3 provides better program, write, and erase efficiency, faster program, write, and erase time, and larger program, write, and erase window than other types of flash memory. Therefore, compared to the flash memory 1 with the floating gate, the flash memory 2 with the SONOS structure 3 according to the present invention is more suitable for use as a memory element. In addition, the SONOS structure 3 is a better embedded flash memory structure. Moreover, since it is compatible with general logic process, the SONOS structure 3 has prosperous future in view of its low manufacturing cost.

In the present invention, the ONO structure 32 has replaced the conventional polysilicon floating gate. The nitride layer 322 is different from the polysilicon and has an electrical conducting characteristic that may solve the problem of entire leakage of the floating gate in the prior art flash memory. In the present invention, the nitride layer 322 may have a thickness about 80 A, and the ONO structure 32 may be produced by way of, for example, thermal growth and LPCVD method. In the present invention, the ONO structure 32 may be, for example, a tunneling oxide-nitride-capping oxide structure.

In the present invention, the lower oxide layer 323 in the ONO structure 32 of the SONOS structure 3 is the tunneling oxide layer capable of effectively controlling the tunneling effect, and has a thickness about 70 A. Since the tunneling oxide layer 323 may effectively control the tunneling effect, the flash memory 2 of the present invention has relatively enhanced data retention ability. In the present invention, the upper oxide layer 321 in the ONO structure 32 is the capping oxide layer, which may be produced by way of high-temperature oxidation and has a thickness about 95A. In the present invention, the ONO structure 32 is used to replace the conventional floating gate. As a result, the difficulty in reading bits is reduced and it is not necessary to use conventional memory element, such as the floating gate in the NAND element. In stead, electric charges are retrieved from the insulated nitride layer 322 located between the two oxide layers 321 and 323. In this way, the flash memory is more reliable for use and the stored current may be effectively controlled. Moreover, the use of photomask in producing a memory element may be reduced, the good yield of the produced memory element is increased, and the size of the memory element may be reduced.

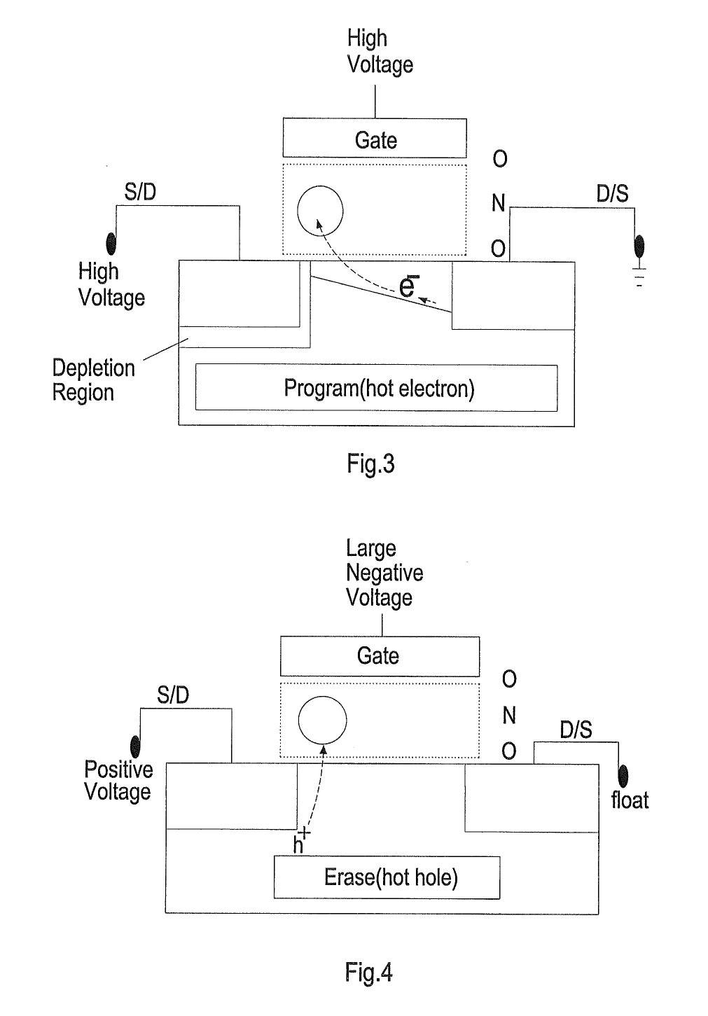

FIG. 3 is a conceptual view showing the flash memory of FIG. 2 in a program operation. Please refer to FIGS. 2 and 3 at the same time. It is noted the flash memory 2 shown in FIG. 3 has a source 4 located at the left side thereof. In this case, when the flash memory 2 is in the program operation, a high voltage about 9V is applied to the gate 31; a voltage about 4V or 4.5V is applied to the drain 5, or alternatively, the drain 5 is grounded; a high voltage is applied to the source 4; and electric current flowed through each bit is 210 μA. On the other hand, when the source 4 is located at the right side of the flash memory 2 and the flash memory 2 is in the program operation, a high voltage about 9V is applied to the gate 31; a voltage about 4V or 4.5V is applied to the source 4, or alternatively, the source 4 is grounded; a high voltage is applied to the drain 5; and electric current flowed through each bit is 210 μA.

Hot electrons 333 at the n channel 33 are injected into the nitride layer 322 of the ONO structure 32 via the lower oxide layer 323. The electric charges in the nitride layer 322 would gather at one side of the nitride layer 322 closer to the source 4. In FIG. 3, the source 4 is located at the left side of the flash memory 2, and the electric charges gather at the left side of the nitride layer 322. In the case the source 4 is located at the right side of the flash memory 2, the electric charges would then gather at the right side of the nitride layer 322. That is, the location at where the electric charges gather in the nitride layer 322 is decided by the position of the source 4 in the flash memory 2. In the present invention, since the hot electrons injected into the nitride layer 322 gather at one side of the nitride layer 322 closer to the source 4, the flash memory 2 with the SONOS structure 3 has better program efficiency, faster program time, and larger program window than other types of flash memory.

FIG. 4 is a conceptual view showing the flash memory of FIG. 2 in an erase operation. Please refer to FIGS. 2 and 4 at the same time. It is noted the flash memory shown in FIG. 4 has a source 4 located at the left side thereof. In this case, when the flash memory 2 is in the erase operation, the gate 31 is applied with a high negative voltage about −6V, the drain 5 has a voltage about 6V or a floating voltage, the source 4 is applied with a high positive voltage, and electric current flowed through each sector is 10 mA.

On the other hand, when the source 4 is located at the right side of the flash memory 2 and the flash memory 2 is in the erase operation, the gate 31 is applied with a high negative voltage about −6V, the source 4 has a voltage about 6V or a floating voltage, the drain 5 is applied with a high positive voltage, and electric current flowed through each sector is 10 mA.

Hot holes 344 at the n channel 33 are injected into the nitride layer 322 of the ONO structure 32 via the lower oxide layer 323. When the hot-hole injection is used as the erase mechanism, the injected hot holes 344 must move in a direction and to a position matching those of the electric charges stored in the nitride layer 322. In FIG. 3, the electric charges gather at the left side of the nitride layer 322. In this case, the hot holes 344 are injected to move toward the left side of the nitride layer 322. That is, the moving direction and the position of the hot holes 344 are decided by the position of the electric charges gathered in the nitride layer 322. Since the hot electrons 333 injected into the nitride layer 322 gather at one side of the nitride layer 322 closer to the source 4, the injected hot holes 344 also move in a direction and to a position corresponding to the side of the nitride layer 322 closer to the source 4. As a result, the flash memory 2 with the SONOS structure 3 has better erase efficiency, faster erase time, and larger erase window, compared to other conventional types of flash memory.

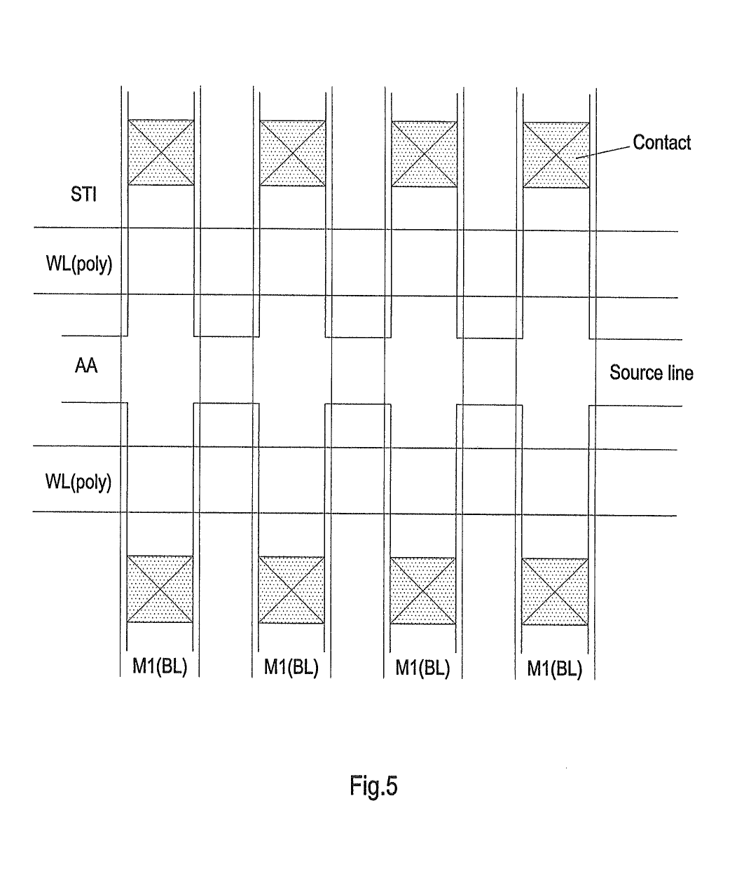

FIG. 5 is a conceptual view showing a silicon-oxide-nitride-oxide-silicon (SONOS) array structure of the flash memory 2 shown in FIG. 2. As shown in FIG. 5, the square areas with cross line are contacts; the word lines (WL) are gates consisting of polysilicon; the bit lines (BL) are drains consisting of metal and are mainly a first metal layer; and the source line is the position at where a voltage is applied. When the bit lines and the word lines are applied with a proper voltage, a single one flash memory cell that is selected by both of the bit lines and the word lines will execute the read operation or the write operation. Please refer to FIGS. 2 and 5 at the same time. The SONOS array consists of a plurality of SONOS structures separately arrayed in a first and a second direction; at least one source line formed in the first direction; at least one word line (WL) formed in the first direction; and at least one bit line (BL) formed in the second direction. In the illustrated embodiment, a reference coordinate of the first direction is defined as the X-direction of a rectangular coordinate, and a reference coordinate of the second direction is defined as the Y-direction of a rectangular coordinate. However, the first and the second direction may also be differently defined without being limited to the above-defined directions. Each of the SONOS structures includes a source, a gate, and a drain formed in the second direction, with the source and the drain exchangeable in their position. The at least one source line electrically connects the sources of all the SONOS structures to one another; the at least one word line electrically connects the gates of all the SONOS structures to one another; and the at least one bit line electrically connects the drains of all SONOS structures to one another via at least one contact. Wherein, the bit line is isolated from the word line and the source line by an insulating layer to avoid any short circuit.

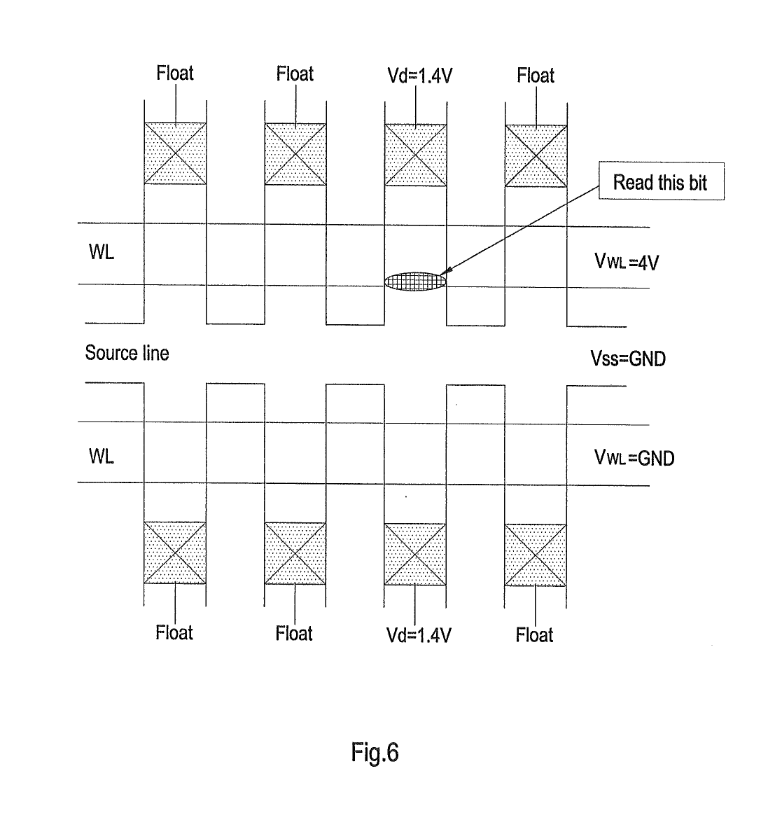

FIG. 6 is a conceptual view showing the flash memory of FIG. 2 under a reverse read bias condition. In the case the source 4 is located at the left side of the flash memory 2 as shown in FIG. 6, for a selected one single flash memory cell, i.e. a flash memory bit to be read, when the bit line (or the drain 5) and the word line (or the gate 31) thereof are separately applied with an appropriate voltage, such as, for example, the bit line (or the drain 5) is applied with a voltage V_{BL} of 1.4V and the word line (or the gate 31) is applied with a voltage V_{WL} of 4V, then the source line thereof is grounded (V_{SL}=GND). As to other flash memory cells that are not selected for reading, the bit lines thereof are floating, and the word lines thereof have a voltage being grounded (V_{WL}=GND).

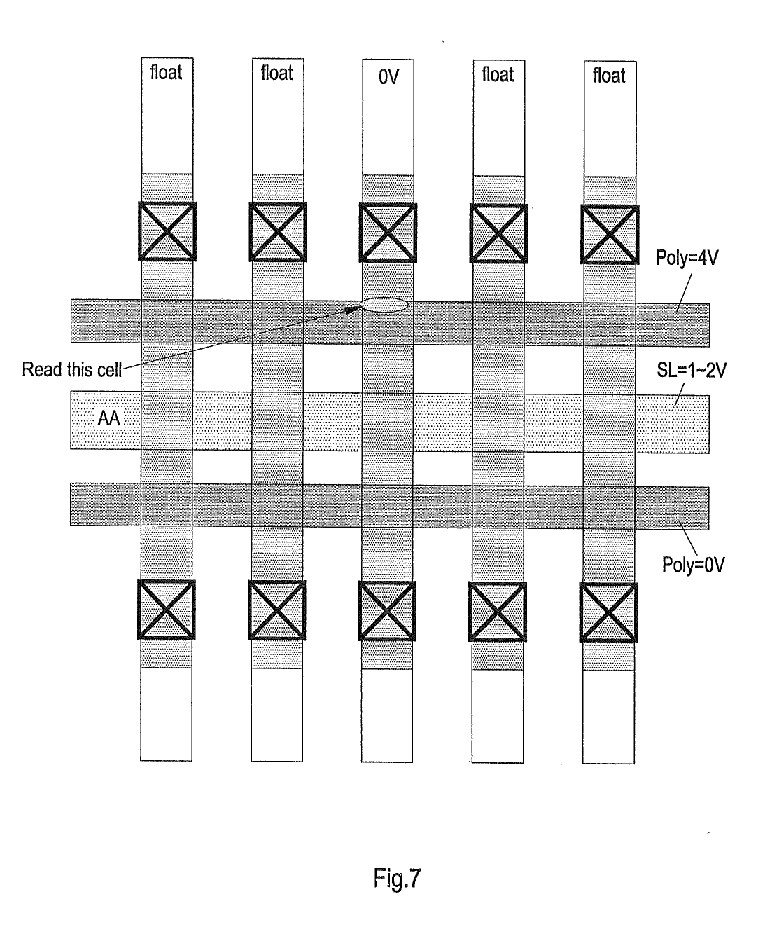

FIG. 7 is a conceptual view showing the flash memory of FIG. 2 under another reverse read bias condition. In the case the source 4 is located at the right side of the flash memory 2 as shown in FIG. 7, for a selected one single flash memory cell, i.e. a flash memory bit to be read, when the bit line (or the drain 5) and the word line (or the gate 31) thereof are separately applied with an appropriate voltage, such as, for example, the bit line (or the drain 5) is grounded (V_{BL}=GND) and the word line (or the gate 31) is applied with a voltage V_{WL} of 4V, then the source line thereof is applied with a voltage V_{SL} of 1˜2V. As to other flash memory cells that are not selected for reading, the bit lines thereof are floating, and the word lines thereof have a voltage being grounded (V_{WL}=GND).

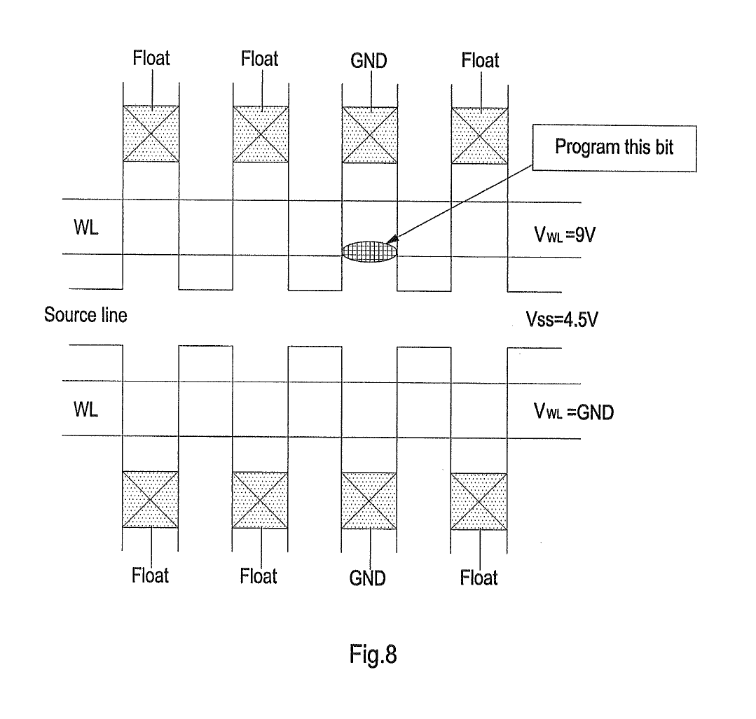

FIG. 8 is a conceptual view showing the flash memory of FIG. 2 under a program bias condition. In the case the source 4 is located at the left side of the flash memory 2 as shown in FIG. 8, for a single flash memory cell selected for programming, i.e. a flash memory bit to be programmed, when the bit line (or the drain 5) and the word line (or the gate 31) thereof are separately applied with an appropriate voltage, such as, for example, the bit line (or the drain 5) is grounded (V_{BL}=GND) and the word line (or the gate 31) is applied with a voltage V_{WL} of 9V, then the source line thereof has a voltage V_{SL} of 4.5V. As to other flash memory cells that are not selected for programming, the bit lines thereof are floating, and the word lines thereof have a voltage being grounded (V_{WL}=GND).

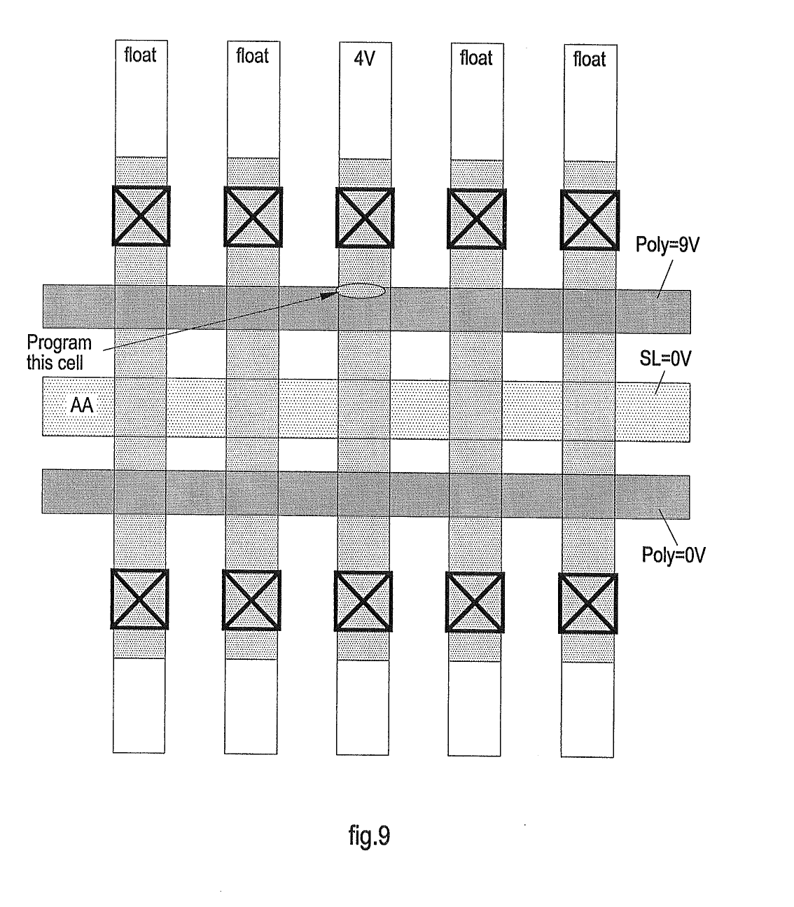

FIG. 9 is a conceptual view showing the flash memory of FIG. 2 under another program bias condition. In the case the source 4 is located at the right side of the flash memory 2 as shown in FIG. 9, for a single flash memory cell selected for programming, i.e. a flash memory bit to be programmed, when the bit line (or the drain 5) and the word line (or the gate 31) thereof are separately applied with an appropriate voltage, such as, for example, the bit line (or the drain 5) has a voltage V_{BL} of 4V and the word line (or the gate 31) is applied with a voltage V_{WL} of 9V, then the source line thereof is grounded (V_{SL}=GND). As to other flash memory cells that are not selected for programming, the bit lines thereof are floating, and the word lines thereof have a voltage being grounded (V_{WL}=GND).

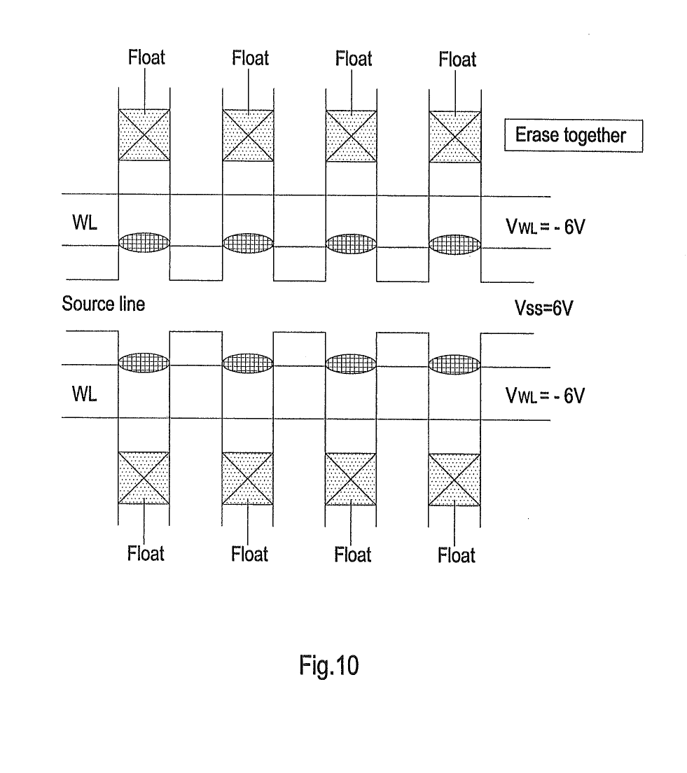

FIG. 10 is a conceptual view showing the flash memory of FIG. 2 under an erase bias condition. In the case the source 4 is located at the left side of the flash memory 2 as shown in FIG. 10, for those flash memory cells selected for erasing, i.e. the flash memory bits to be erased, when the bit lines (or the drains 5) and the word lines (or the gates 31) thereof are separately applied with an appropriate voltage, such as, for example, the selected bit lines (or the drains 5) are floating and the selected word lines (or the gates 31) are applied with a voltage V_{WL} of −6V, then the source lines thereof have a voltage V_{SL} of 6V. As to other flash memory cells that are not selected for erasing, the bit lines thereof are floating, and the word lines thereof have a voltage being floating or a positive voltage.

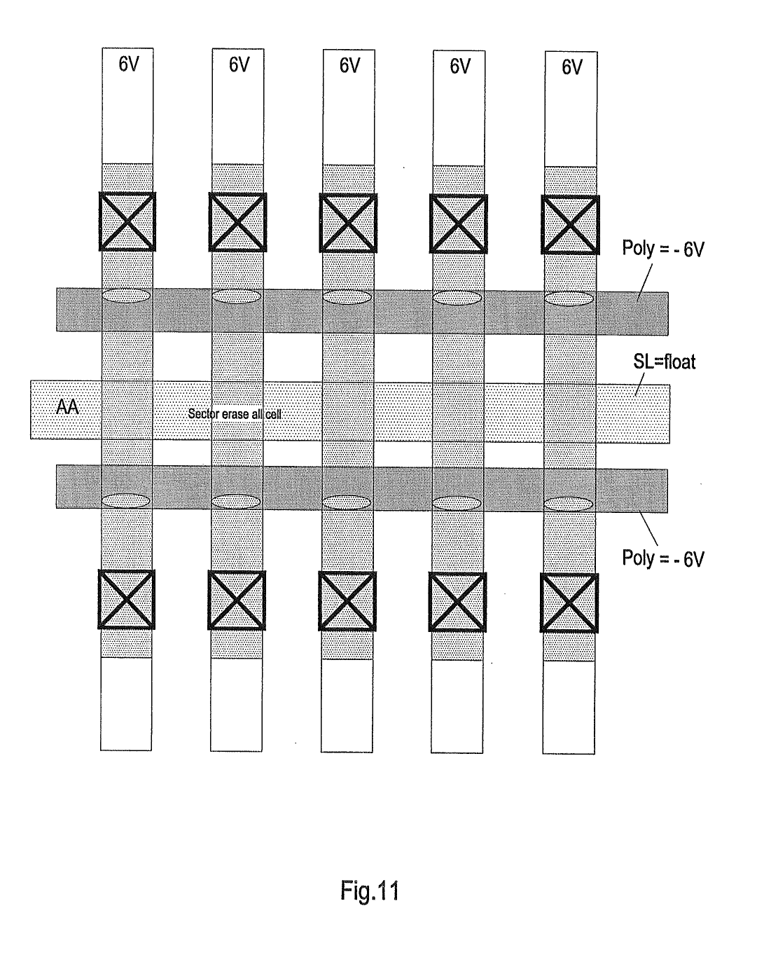

FIG. 11 is a conceptual view showing the flash memory of FIG. 2 under another erase bias condition. In the case the source 4 is located at the right side of the flash memory 2 as shown in FIG. 11, for those flash memory cells selected for erasing, i.e. the flash memory bits to be erased, when the bit lines (or the drains 5) and the word lines (or the gates 31) are separately applied with an appropriate voltage, such as, for example, the selected bit lines (or the drains 5) have a voltage V_{BL} of 6V, the selected word lines (or the gates 31) are applied with a voltage V_{WL} of −6V, then the source lines thereof have a voltage being floating. As to other flash memory cells that are not selected for erasing, the bit lines thereof are floating, and the word lines thereof have a voltage being floating or a positive voltage.

In conclusion, the present invention provides a flash memory, and particularly a flash memory with an SONOS cell structure. The flash memory of the present invention uses the channel-hot-electron injection as the write mechanism thereof to have the characteristic of localized trapping, and uses the hot-hole injection as the erase mechanism thereof. Therefore, the flash memory of the present invention provides better data program, read, and erase efficiency, faster program, read, and erase time, as well as larger program, read, and erase window, compared to other types of conventional flash memory. Moreover, the flash memory of the present invention uses the ONO structure to replace the floating gate, and thereby solves the problem of an entire leakage caused by the local leakage of the floating gate. The advantages of the flash memory of the present invention may be summarized as follows:
1. The flash memory of the present invention has an SONOS cell structure, uses the channel-hot-electron injection as the write mechanism thereof, has the characteristic of localized trapping, and uses the hot-hole injection as the erase mechanism thereof, and is therefore very helpful in multi-bit memory.
2. By using the ONO film to replace the floating gate, the flash memory of the present invention is able to solve the problem of an entire leakage caused by a local leakage of the floating gate.
3. The present invention enables the miniaturization of flash memory without the problem of data mutual interference, so that the retention of stored data is largely improved.
4. The flash memory of the present invention may be easily integrated into the CMOS process to largely reduce the manufacturing cost, and is therefore highly suitable for use as a memory element.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A flash memory applied in NAND (NOT AND) and/or NOR (NOT OR) flash memory, comprising:
a silicon-oxide-nitride-oxide-silicon (SONOS) array consisting of a plurality of SONOS structures separately arrayed in a first and a second direction; each of the SONOS structures including a source, a gate, and a drain formed in the second direction; wherein the first direction and the second direction are defined as any two different directions in a plane defined by the X and Y axes of a rectangular coordinate, and the source and the drain are exchangeable in position;
at least one source line formed in the first direction to electrically connect the sources of all the SONOS structures to one another;
at least one word line formed in the first direction to electrically connect the gates of all the SONOS structures to one another; and
at least one bit line formed in the second direction to electrically connect the drains of all the SONOS structures via at least one contact; wherein the bit line is isolated from the word line and the source line by an insulating layer to avoid short circuit.

2. The flash memory as claimed in claim 1, wherein the SONOS structure includes an oxide-nitride-oxide (ONO) structure.

3. The flash memory as claimed in claim 2, wherein the flash memory uses channel-hot-electron injection as a write mechanism thereof to have a characteristic of localized trapping.

4. The flash memory as claimed in claim 3, wherein the flash memory is an n-channel flash memory.

5. The flash memory as claimed in claim 3, wherein the flash memory is a p-channel flash memory.

6. The flash memory as claimed in claim 2, wherein one of the two oxide layers in the ONO structure is a tunneling oxide layer, and the other one a capping oxide layer.

7. The flash memory as claimed in claim 2, wherein when the flash memory is under a reverse read bias condition, the drain of a flash memory bit being read and the silicon layers of the SONOS structure being read are separately applied with a voltage, and the sources are grounded, while the drains of other flash memory cells that are not selected for reading are floating and the silicon layers of the SONOS structures that are not selected for reading have a voltage being grounded.

8. The flash memory as claimed in claim 2, wherein when the flash memory is under a reverse read bias condition, the source of a flash memory bit being read and the silicon layers of the SONOS structure being read are separately applied with a voltage, and the drains are grounded, while the sources of other flash memory cells that are not selected for reading are floating and the silicon layers of the SONOS structures that are not selected for reading have a voltage being grounded.

9. The flash memory as claimed in claim 2, wherein when the flash memory is under a program bias condition, the source of a flash memory bit being programmed and the silicon layers of the SONOS structure being programmed are separately applied with a voltage, and the drains are grounded, while the drains of other flash memory cells that are not selected for programming are floating and the silicon layers of the SONOS structures that are not selected for programming have a voltage being grounded.

10. The flash memory as claimed in claim 2, wherein when the flash memory is under a program bias condition, the drain of a flash memory bit being programmed and the silicon layers of the SONOS structure being programmed are separately applied with a voltage, and the sources are grounded, while the sources of other flash memory cells that are not selected for programming are floating and the silicon layers of the SONOS structures that are not selected for programming have a voltage being grounded.

11. The flash memory as claimed in claim 2, wherein when the flash memory is under an erase bias condition, the sources of flash memory bits being erased and the silicon layers of the SONOS structures being erased are separately applied with a voltage, and the drains are floating, while the drains of other flash memory cells that are not selected for erasing are floating and the silicon layers of the SONOS structures that are not selected for erasing have a floating or a positive voltage.

12. The flash memory as claimed in claim 2, wherein when the flash memory is under an erase bias condition, the drains of flash memory bits being erased and the silicon layers of the SONOS structures being erased are separately applied with a voltage, and the sources are floating, while the sources of other flash memory cells that are not selected for erasing are floating and the silicon layers of the SONOS structures that are not selected for erasing have a floating or a positive voltage.

13. The flash memory as claimed in claim 2, wherein the sources of the flash memory are connected in parallel via a silicon substrate, the gates are connected in parallel via polysilicon, and the drains are connected in parallel via metal wires.
